(19) United States
(12) Patent Application Publication
(10) Pub. No.: US 2025/0185261 A1
(43) Pub. Date: Jun. 5, 2025

(54) CAPACITOR AND SEMICONDUCTOR DEVICE AND ELECTRONIC DEVICE

(71) Applicant: SAMSUNG ELECTRONICS CO., LTD., Suwon-si (KR)

(72) Inventors: Chang Seok LEE, Suwon-si (KR); Sangwon KIM, Suwon-si (KR); Keun Wook SHIN, Suwon-si (KR); Daejin YANG, Suwon-si (KR)

(21) Appl. No.: 18/748,530

(22) Filed: Jun. 20, 2024

(30) Foreign Application Priority Data
Dec. 4, 2023 (KR) 10-2023-0173786

(51) Int. Cl. H01L 27/06

(52) U.S. Cl. CPC H10D 1/042; H10D 1/696; H10D 1/716; H10D 84/811

(57) ABSTRACT

A capacitor, and a semiconductor device including the capacitor and an electronic device including the capacitor or the semiconductor device. The capacitor includes a first electrode, a second electrode facing the first electrode, and a dielectric film between the first electrode and the second electrode. The first electrode includes a topological material.

### CROSS-REFERENCE TO RELATED APPLICATION

This application claims priority to Korean Patent Application No. 10-2023-0173786 filed in the Korean Intellectual Property Office on Dec. 4, 2023 and all the benefits accruing therefrom under 35 U.S.C. § 119, the entire contents of which are herein incorporated by reference.

### BACKGROUND OF THE INVENTION

### (a) Field of the Invention

Capacitors, semiconductor devices, and electronic devices are disclosed.

### (b) Description of the Related Art

As the demand for digital devices increases, the demand for integrated circuit devices is also rapidly increasing. Integrated circuit devices are of interest to reduce the size of unit cells, and accordingly, there is a need for materials and structures suitable for scaling to meet system requirements.

### SUMMARY OF THE INVENTION

A capacitor includes a first electrode including a topological material, a second electrode facing the first electrode, and a dielectric film between the first electrode and the second electrode.

The first electrode may include a first conductive layer including a conductor and a second conductive layer including the topological material. The conductor and the topological material may be different in chemical composition.

The conductor included in the first conductive layer may include metal oxide.

The conductor included in the first conductive layer may include molybdenum oxide.

The topological material and the metal oxide may commonly include at least one same metal element.

The topological material and the metal oxide may each include molybdenum (Mo).

The metal oxide may include a molybdenum oxide of the formula MoOₓ wherein 2≤x≤3, and the topological material may include MoP, MON, MOC, MoTe₂, MoSTe, MoSi₂, MoSeTe, Mo_{(1-z)}W_{z}Te₂ wherein 0<z≤1, or a combination thereof.

A first surface of the second conductive layer may be in contact with the dielectric film, and an opposite second surface of the second conductive layer may be in contact with the first conductive layer.

The dielectric film may include a dielectric material which is a product of epitaxial growth on the first surface of the second conductive layer having a dielectric constant that is greater than a dielectric constant of silicon oxide.

The topological material may include MoP, MON, MoC, MoTe₂, MoSTe, MoSi₂, MoSeTe, Mo_{(1-z)}W_{z}Te₂ wherein 0<z≤1, or a combination thereof, and the dielectric may include TePb, PbSe, PbS, Bi₂Te₃, TiO₂, BizSe₃, LiNbO₃, LiTaO₃, Ge(Bi₃O₅)₄, LaAlO₃, CeO₂, Ge, InSb, GaSb, NdGaO₃, ZrO₂, TeO₂, InP, GaAs, YAlO₃, Te₂Mo, CdWO₄, or a combination thereof.

The first electrode may further include a third conductive layer spaced apart from the second conductive layer and the third conductive layer disposed on a surface of the first conductive layer.

The third conductive layer may include the topological material, Ti, TiN, TiON, or a combination thereof.

In another embodiment, a semiconductor device includes a semiconductor substrate, a transistor, wherein the transistor may be integrated in the semiconductor substrate or disposed on the semiconductor substrate, and the capacitor may be electrically connected to the transistor.

A semiconductor device includes a semiconductor substrate, a transistor, wherein the transistor is integrated in the semiconductor substrate or disposed on the semiconductor substrate, a capacitor electrically connected to the transistor and including a first electrode, a dielectric film, and a second electrode, wherein the first electrode includes a first conductive layer including a first conductor, and a second conductive layer in contact with the dielectric film and including a second conductor of a different chemical composition than the first conductor, and the first conductor and the second conductor include at least one same metal element.

A resistivity of the first electrode may be less than a resistivity of the first conductive layer.

The first conductor may include a molybdenum oxide of the formula MoOₓ wherein 2≤x≤3, and the second conductor may include MoP, MON, MoC, MoTe₂, MoSTe, MoSi₂, MoSeTe, Mo_{(1-z)}W_{z}Te₂ wherein 0<z≤1, or a combination thereof.

The first electrode may further include a third conductive layer disposed on a surface of the first conductive layer and including the topological material, Ti, TIN, TION, or a combination thereof.

The semiconductor device may further include an interlayer insulating film on the transistor, and the capacitor may be formed in a trench in the interlayer insulating film.

In another embodiment, an electronic device including the capacitor or the semiconductor device is provided.

A method of manufacturing a capacitor comprises depositing a conductor on a substrate to form a first conductive layer; disposing a second conductive layer on the first conductive layer to form a first electrode; disposing a dielectric film on the first electrode, wherein the second conductive layer is disposed between the dielectric film and the first conductive layer to form a composite; and disposing a second electrode on the composite, wherein the dielectric film is disposed between the first electrode and the second electrode to manufacture the capacitor, wherein the second conductive layer comprises a topological material, the first conductive layer comprises a metal oxide, and the topological material and the metal oxide comprise at least one same metal element.

### BRIEF DESCRIPTION OF THE DRAWINGS

FIG. 1 is a cross-sectional view illustrating an embodiment of a capacitor,

FIG. 2 is a cross-sectional view illustrating another embodiment of a capacitor,

FIG. 3 is a cross-sectional view illustrating another embodiment of a capacitor,

FIG. 4 is a cross-sectional view illustrating an embodiment of a semiconductor device, and

FIG. 5 is a cross-sectional view illustrating another embodiment of a semiconductor device.

### DETAILED DESCRIPTION OF THE EMBODIMENTS

Hereinafter, the embodiments will be described in detail so that those of ordinary skill in the art can easily implement them. However, the actually applied structure may be implemented in several different forms and is not limited to the embodiments described herein.

The terms used herein are merely for the purpose of describing example embodiments, and are not intended to limit the present disclosure. The singular expression includes the plural expression unless the context clearly dictates otherwise.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Throughout the specification, the terms “comprise” or “have” are intended to specify the presence of stated features, integers, steps, operations, constituent elements, components or a combination thereof, but do not preclude the presence or addition of one or more other features, integers, steps, operations, constituent elements, components, and/or groups thereof.

In the drawings, the thickness of layers and regions may be exaggerated for clarity, and like reference numerals designate like elements throughout the specification. It will be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “over” another component, the component can be directly on, under, on the left of, or on the right of the other component, or can be on, under, on the left of, or on the right of the other component in a non-contact manner. In addition, unless explicitly described to the contrary, the word “comprise,” and variations such as “comprises” or “comprising,” will be understood to imply the inclusion of stated elements but not the exclusion of any other elements.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer” includes a construction having a shape formed on a part of a region, in addition to a construction having a shape formed on an entire region.

As used herein, the term “the” or similar indicative terms correspond to both the singular form and the plural form. The steps of all methods described herein can be performed in any suitable order unless otherwise indicated herein or otherwise clearly contradicted by context.

Also, terms such as “unit.” “module,” etc., as used in the present specification may refer to a part for processing at least one function or action and may be implemented as hardware, software, or a combination of hardware and software.

The connecting lines, or connectors shown in the various figures presented are intended to represent example functional relationships and/or physical or logical couplings between the various elements. It should be noted that many alternative or additional functional relationships, physical connections or logical connections may be present in a practical apparatus.

As used herein, “at least one of A, B, or C,” “one of A, B, C, or a combination thereof” and “one of A, B, C, and a combination thereof” refer to each constituent element, and a combination thereof (e.g., A; B; C; A and B; A and C; B and C; or A, B and C).

Herein, “combination thereof” refers to a mixture, a stacked structure, a composite, an alloy, a blend, for example.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within +10%, +5%, +3%, or +1% of the indicated value or within a standard deviation.

Hereinafter, “metal” is interpreted as a concept including metals and metalloids (semimetals).

Hereinafter, an example of a capacitor according to some example embodiments will be described with reference to the drawings.

The disclosed capacitor may be suitable for scaling and capable of implementing improved electrical performance. In an embodiment, a semiconductor device includes the capacitor. In an embodiment, an electronic device includes the capacitor or the semiconductor device. The electrical performance of capacitors and semiconductor devices including the same may be improved.

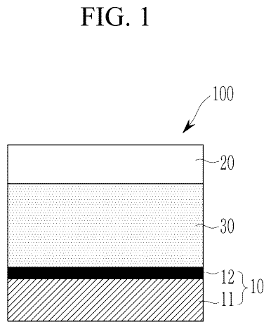

FIG. 1 is a cross-sectional view illustrating an embodiment of a capacitor.

Referring to FIG. 1, the capacitor 100 according to an embodiment includes a first electrode 10 and a second electrode 20 facing each other, and a dielectric film 30 between the first electrode 10 and the second electrode 20.

The first electrode 10 includes a topological material.

The topological material is also called a topological metal, and may further include at least one metal element and optionally a semi-metal element and/or a non-metallic element. As used herein, “topological material”, refers to conducting materials with gapless band structures and nontrivial edge-localized resonances. The topological material may be a single crystalline compound or a polycrystalline compound with a predetermined crystal structure, for example, a close-packed hexagonal lattice (HCP), but is not limited thereto.

Unlike general bulk metals, the topological material may have less electron scattering at the surface and grain boundaries, and thus it may reduce or prevent a rapid increase in resistivity even when the surface area to volume increases.

For example, copper electrodes including copper Cu, which is one of the general bulk metals, may be affected in the transport of electrons by an increase in the electron scattering at the surface and/or grain boundaries of the metal due to a decrease in line width, and particularly, when the line width narrows to nanometer level of less than about 10 nanometers (nm), the influence of the line width may sharply increase, increasing resistivity of the copper electrodes and also, deteriorating performance due to exothermic generation.

However, the topological material, as described above, may have low electron scattering at the surface and grain boundaries, and thus very small or no resistivity change due to the decrease in a line width and particularly, exhibit no sharp increase of resistivity, even when the line width narrows to nanometer level of less than about 10 nm. For example, the resistivity change of the topological material may be less than about 2 times due to about 10% decrease of the line width, less than or equal to about 1.8 times, less than or equal to about 1.5 times, or less than or equal to about 1.2 times. For example, the resistivity change of the topological material due to a decrease of the line width may be demonstrated by comparing resistivity of a topological material with a line width of about 3 nm to that of a topological material with a line width of about 40 nm, wherein the resistivity of the topological material with a line width of about 3 nm and that of the topological material with a line width of about 40 nm may have a resistivity difference of less than about 10 times, less than or equal to about 8 times, less than or equal to about 7 time, less than or equal to about 5 times, less than or equal to about 3 times, less than or equal to about 2 times, less than or equal to about 1.8 times, less than or equal to about 1.5 times, or less than or equal to about 1.2 times. This may be a significantly less resistivity, compared with about 20 times or greater resistivity difference between copper with a line width of about 3 nm and copper with a line width of about 40 nm.

The first electrode 10 of the capacitor 100 may include a first conductive layer 11 and a second conductive layer 12 including a topological material. The second conductive layer 12 may be between the first conductive layer 11 and the dielectric film 30.

The first conductive layer 11 may include a conductor of a different chemical composition from the topological material. “Chemical composition”, as used herein, refers to the identity, arrangement, and ratio of chemical elements of a chemical substance. A “different chemical composition”, as used herein, refers to a difference in the identity, in the arrangement, in the ratio of chemical elements, or a combination thereof of for at least one chemical substance in a comparison between a first material and a second material.

The first conductive layer 11 may include, for example, a metal oxide and for example, a transition metal oxide. For example, the first conductive layer 11 may include a molybdenum oxide of the formula MoOₓ wherein 2≤x≤3. The molybdenum oxide may have relatively low resistivity (e.g., about 10-4 to about 10⁻² ohm centimeters, Ωcm) to effectively reduce or prevent a signal delay and also, a relatively high work function to effectively reduce a leakage current. In addition, the molybdenum oxide of the formula MoOₓ may be effectively formed into a thin conductive layer with a thickness of several to tens of nanometers through atomic layer deposition (ALD) and have relatively high thermal stability, and thus effectively reduce or prevent degradation during its subsequent high-temperature process.

The second conductive layer 12 may include the aforementioned topological material. The second conductive layer 12 may be disposed between the dielectric film 30 and the first conductive layer 11. The second conductive layer 12, for example, may be in contact with the dielectric film 30. For example, a first surface of the second conductive layer 12 may be in contact with the dielectric film 30, and an opposite second surface of the second conductive layer 12 may be in contact with the first conductive layer 11.

The second conductive layer 12 may be between the first conductive layer 11 and the dielectric film 30 to improve oxidation resistance and simultaneously, separate the first conductive layer 11 from the dielectric film 30 to prevent formation of an additional interface layer between the first conductive layer 11 and the dielectric film 30 during a subsequent high-temperature process. Accordingly, a leakage current, which may be caused by the interface layer formed by a reaction of the conductor (e.g., metal oxide such as molybdenum oxide) included in the first conductive layer 11 and a dielectric included in the dielectric film 30, may be effectively reduced or prevented, and in addition, deterioration of dielectric performance of the dielectric film 30 may be effectively reduced or prevented.

The second conductive layer 12 includes the aforementioned topological material, and thus may reduce or prevent a sharp increase in resistivity due to a decrease in line width and particularly, such as reducing or preventing a sharp increase in resistivity even when the line width narrows to a nanometer level of less than about 10 nm. Accordingly, the resistivity of the first electrode 10 including the second conductive layer 12 may be less than a resistivity of the first conductive layer 11. For example, the resistivity of the first electrode 10 with a line width of less than about 10 nm may be about 2 or more times less (e.g., about 2-fold less or more than about 2-fold less) than the resistivity of the first conductive layer 11, about 3 times or more, about 5 times or more, about 10 times or more, about 15 times or more, or about 20 times or more less than the resistivity of the first conductive layer 11, and about 2 times to about 300 times, about 3 times to about 300 times, about 5 times to about 300 times, about 10 times to about 300 times, about 15 times to about 300 times, or about 20 times to about 300 times less than the resistivity of the first conductive layer 11.

For example, the conductor included in the first conductive layer 11 and the topological material included in the second conductive layer 12 may include at least one metal element in common (further referred to herein as “at least one same metal element” or “at least one common metal element”). For example, the first conductive layer 11 may include the aforementioned molybdenum oxide of the formula MoOₓ wherein 2≤x≤3, and the second conductive layer 12 may include a topological material including molybdenum (Mo). For example, the first conductive layer 11 may include molybdenum oxide of the formula MoOₓ wherein 2≤x≤3, and the second conductive layer 12 may include a topological material including MoP, MON, MOC, MoTe₂, MoSTe, MoSi₂, MoSeTe, Mo_{(1-z)}W_{z}Te₂ wherein 0<z≤1, or a combination thereof. For example, the first conductive layer 11 may include molybdenum oxide of the formula MoOₓ wherein 2≤x≤3, and the second conductive layer 12 may include a topological material including MoP, MON, MoC, MoTe₂, or a combination thereof. Herein, a fraction of elements contained in each topological material may be determined chemically and quantitatively, and even when expressed as about 1:1, for example, it may be actually a fraction of about 0.8:1 to about 1.2:1 or about 0.9:1 to about 1.1:1.

In this way, since the conductor included in the first conductive layer 11 and the topological material included in the second conductive layer 12 include at least one same metal element, the interface of the first conductive layer 11 and the second conductive layer 12 may have a continuous crystal structure due to the common metal element. Accordingly, the first conductive layer 11 and the second conductive layer 12 may form a continuous interface to have a substantially seamless interface and thereby reducing contact resistance.

For example, the first conductive layer 11 and the second conductive layer 12 may be formed through a continuous process. For example, after forming the first conductive layer 11 with a predetermined thickness, other elements (e.g., semi-metal elements and/or non-metallic elements) for the topological material may be supplied (e.g., doped) to a portion of the thickness of the first conductive layer 11 and then, heat-treated to form the second conductive layer 12 including the topological material on the first conductive layer 11. Through the supplying (e.g., doping) of other elements (e.g., semi-metal elements and/or non-metallic elements) for the topological material, elements (e.g., oxygen of a metal oxide) constituting the first conductive layer 11 may be substituted with the other elements (e.g., semi-metal elements and/or non-metallic elements) to form the topological material. For example, a portion of the molybdenum oxide of the formula MoOₓ wherein 2≤x≤3 may be converted to MoP through a phosphorus (P) doping process (a phosphorization process) of supplying phosphorus (P). Herein, the element substitution may be determined by a macroscopic color change, a texture change as determined by optical microscopy, a Raman spectrum change as determined by an X-ray diffraction (XRD) analysis, an element analysis as determined by energy dispersive spectroscopy (EDS) analysis, and/or the like.

However, the first conductive layer 11 and the second conductive layer 12, which are not limited thereto, may be formed through a separate process, for example, the conductor (e.g., a molybdenum oxide of the formula MoOₓ wherein 2≤x≤3) for the first conductive layer 11 is deposited to form the first conductive layer 11, and then, the topological material (e.g., MoP) may be deposited on the first conductive layer 11 to form the second conductive layer 12.

A thickness of the first electrode 10 may be about 1 nm to about 50 nm and within the range, about 1 nm to about 40 nm, about 1 nm to about 30 nm, about 1 nm to about 20 nm, about 1 nm to about 15 nm, about 1 nm to about 10 nm, about 1 nm to about 9 nm, about 1 nm to about 7 nm, about 1 nm to about 5 nm, or about 1 nm to about 4 nm.

A thickness ratio of the first conductive layer 11 and the second conductive layer 12 of the first electrode 10 may be about 1:9 to about 9:1, about 2:8 to about 8:2, about 3:7 to about 7:3, about 4:6 to about 6:4, or about 5:5. For example, the first conductive layer 11 may be thicker than the second conductive layer 12 and specifically, the thickness of the first conductive layer 11 is about 1.5 times to about 20 times, about 2 times to about 20 times or about 5 times to about 20 times thicker than the thickness of the second conductive layer 12.

The second electrode 20 may include, for example, a metal, a metal nitride, a metal oxide, a metal oxynitride, or a combination thereof. For example, the second electrode 20 may include Ti, TIN, TION, TaN, MON, CON, TiAIN, TaAlN, W, WO_{y} wherein 2≤y≤3, Ru, RuO₂, SrRiO₃, Ir, IrO₂, Pt, PtO, SrRuO₃, or a combination thereof, but is not limited thereto.

A thickness of the second electrode 30 may be about 1 nm to about 1 micrometer (μm), about 1 nm to about 800 nm, about 1 nm to about 500 nm, about 1 nm to about 300 nm, or about 1 nm to about 100 nm.

The dielectric film 30 may be between the first electrode 10 and the second electrode 20, wherein for example, a first surface of the dielectric film 30 may be in contact with the first electrode 10 (e.g., the second conductive layer 12), while an opposite second surface of the dielectric film 30 may be in contact with the second electrode 20.

The dielectric film 30 may include a dielectric material having a dielectric constant that is greater than a dielectric constant of silicon oxide, a so-called a high-k dielectric. The dielectric constant of a high-k dielectric may be greater than or equal to about 15. For example, the dielectric film 30 may include a high-k dielectric capable of epitaxial growth on the second conductive layer 12. For example, the dielectric film 30 of the capacitor 100 may include a dielectric material which is a product of epitaxial growth on a first surface of the second conductive layer 12.

For example, when the second conductive layer 12 includes the aforementioned topological material (e.g., molybdenum-containing topological material, such as MoP), the dielectric film 30 may be formed of TePb, PbSe, PbS, Bi₂Te₃, TiO₂, BizSe₃, LiNbO₃, LiTaO₃, Ge(Bi₃O₅)₄, LaAlO₃, CeO₂, Ge, InSb, GaSb, NdGaO₃, ZrO₂, TeO₂, InP, GaAs, YAlO₃, Te₂Mo, CdWO₄, or a combination thereof.

A thickness of the dielectric film 30 may be about 1 nm to about 200 nm, about 1 nm to about 150 nm, about 1 nm to about 100 nm, about 2 nm to about 80 nm, about 2 nm to about 50 nm, or about 2 nm to about 30 nm.

In this way, the capacitor 100 according to the present embodiments includes the first electrode 10 including the topological material to reduce or prevent a sharp increase in resistivity according to a decrease of line width, thereby, effectively reducing resistance of an electrode with a fine line width and ultimately, providing the capacitor 100 with superior electrical performance.

In addition, the capacitor 100 according to the present embodiments, for example, includes the first conductive layer 11 including a conductor such as molybdenum oxide to effectively improve a leakage current generated from a conventional TiN electrode, and in addition, disposes the second conductive layer 12 including a topological material between the first conductive layer 11 and the dielectric film 30 to improve oxidation resistance and simultaneously prevent additional formation of an interface layer between first conductive layer 11 and dielectric film 30 in a subsequent high-temperature process, thereby, providing further improved electrical performance of the capacitor 100.

In addition, the capacitor 100 according to the present embodiments includes at least one same metal element in the first conductive layer 11 and the second conductive layer 12 of the first electrode 10 to effectively reduce contact resistance of the first conductive layer 11 and the second conductive layer 12, thereby, further improving the electrical performance of the capacitor.

Hereinafter, further embodiments of a capacitor will be described.

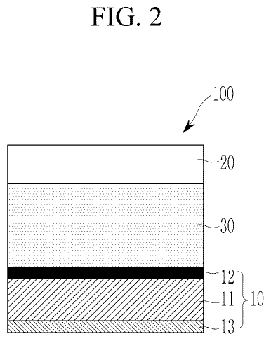

FIG. 2 is a cross-sectional view illustrating an embodiment of a capacitor.

Referring to FIG. 2, the capacitor 100 may include the first electrode 10, the second electrode 20, and the dielectric film 30 between the first electrode 10 and the second electrode 20, wherein the first electrode 10 includes the first conductive layer 11 and the second conductive layer 12.

The first electrode 10 of the capacitor 100 may further include a third conductive layer 13. The third conductive layer 13 may be spaced apart from the second conductive layer 12 and disposed on a surface of the first conductive layer 11, wherein for example, the third conductive layer 13, the first conductive layer 11, and the second conductive layer 12 may be stacked in order, such that the second conductive layer is disposed on a first surface of the first conductive layer and the third conductive layer is disposed on an opposite second surface of the first conductive layer.

The third conductive layer 13 may be under the first conductive layer to increase crystallinity of the first conductive layer 11 during the formation of the first conductive layer 11.

The third conductive layer 13 may include a topological material, Ti, TiN, TION, or a combination thereof.

For example, the third conductive layer 13 may include the aforementioned topological material. The topological material included in the third conductive layer 13 and the topological material included in the second conductive layer 12 may be the same chemical composition or a different chemical composition from each other. For example, the second conductive layer 12 and the third conductive layer 13 may each independently include MoP, MoN, MoC, MoTe₂, MoSTe, MoSi₂, MoSeTe, Mo_{(1-z)}W_{z}Te₂ wherein 0<z≤1, or a combination thereof. For example, the second conductive layer 12 and the third conductive layer 13 may each include MoP.

A thickness ratio of the first conductive layer 11 and the third conductive layer 13 of the first electrode 10 may be about 1:9 to about 9:1, about 2:8 to about 8:2, about 3:7 to about 7:3, about 4:6 to about 6:4, or about 5:5. For example, the thickness of the first conductive layer 11 may be about 1.5 times to about 20 times, about 2 times to about 20 times, or about 5 times to about 20 times thicker than the thickness of the third conductive layer 13.

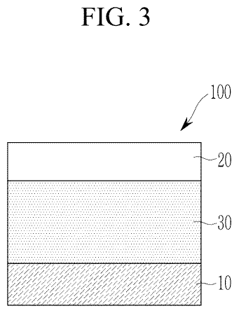

FIG. 3 is a cross-sectional view illustrating an embodiment of a capacitor.

Referring to FIG. 3, the capacitor 100 according to some example embodiments, like in the aforementioned embodiments, includes the first electrode 10, the second electrode 20, and the dielectric film 30 between the first electrode 10 and the second electrode 20. However, the first electrode 10 of the capacitor 100 according to the present embodiments may be a monolayer including a topological material, unlike in the aforementioned embodiments. The topological material may be, for example, MoP, MoN, MoC, MoTe₂, MoSTe, MoSi₂, MoSeTe, Mo_{(1-z)}W_{z}Te₂ wherein 0<z≤1, or a combination thereof.

As described above, the topological material may reduce or prevent a rapid increase in resistivity due to a decrease in line width, and thus further reduce resistance of the first electrode 10, thereby, improving electrical performance of the capacitor 100.

The above capacitor 100 may be included in a semiconductor device. The semiconductor device may be, for example, an integrated circuit (IC) device including a transistor and a capacitor, for example, a memory device, such as, a non-volatile memory device.

Hereinafter, further embodiments of a semiconductor device are illustrated with reference to the drawings. Herein, a dynamic random-access memory (DRAM) device is illustrated as one example of the semiconductor device.

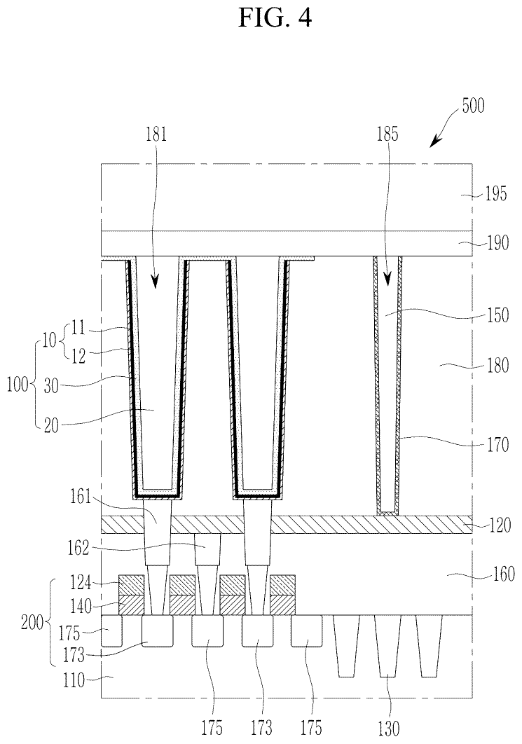

FIG. 4 is a cross-sectional view illustrating an embodiment of the semiconductor device.

Referring to FIG. 4, an embodiment of the semiconductor device 500 includes a semiconductor substrate 110, a transistor 200, and the capacitor 100.

The semiconductor substrate 110 may include silicon; germanium; silicon-germanium; Group III-V compounds such as GaP, GaAs, and GaSb; or a combination thereof. For example, the semiconductor substrate 110 may be a silicon-on-insulator (SOI) substrate or a germanium-on-insulator (GOI) substrate.

The transistor 200 may be disposed in an active region defined by a shallow trench isolation (STI) film 130 in the semiconductor substrate 110 and electrically connected to a bit line 120 and the capacitor 100 to play a role of switching. The transistor 200 may be a field effect transistor (FET) including a source region 173, a drain region 175, a gate electrode 124, and a gate insulator 140. The FET may have various structures, for example, a fin field effect transistor (FinFET), a gate-all-around field effect transistor (GAAFET), a multi-bridge channel field effect transistor (MBCFET), a complementary field effect transistor (CFET), or a vertical field effect transistor (VFET), but is not limited thereto.

The source region 173 and the drain region 175 may be provided in the semiconductor substrate 110 and arranged to be spaced apart along an in-plane direction of the semiconductor substrate 110. The source region 173 and the drain region 175 may be conductive regions doped with p-type or n-type impurities at a high concentration in the semiconductor substrate 110, wherein in the case of an n-type transistor, the source region 173 and the drain region 175 may be doped with the n-type impurities at a high concentration, and in the case of a p-type transistor, the source region 173 and the drain region 175 may be doped with p-type impurities at a high concentration. The source region 173 may be electrically connected to the capacitor 100, and the drain region 175 may be electrically connected to the bit line 120.

The gate electrode 124 may be formed on the semiconductor substrate 110 and between the source region 173 and the drain region 175. The gate electrode 124 may include a low resistance conductor, for example, Ti, TIN, TION, or a combination thereof. The gate electrode 124 may be formed of one layer, or greater than or equal to two layers.

The gate insulating layer 140 may be between the gate electrode 124 and the semiconductor substrate 110 and include a gate dielectric material. The gate dielectric material may include, for example, an oxide, a nitride, an oxynitride, or a combination thereof including silicon, aluminum, hafnium, lanthanum, zirconium, tantalum, yttrium, titanium, barium, strontium or an alloy thereof, but is not limited thereto.

On the transistor 200, interlayer insulating films 160 and 180 may be formed. The interlayer insulating films 160 and 180 may include, for example, an oxide, a nitride, an oxynitride, or a combination thereof including silicon, aluminum, hafnium, lanthanum, zirconium, tantalum, yttrium, titanium, barium, strontium, or an alloy thereof, but are not limited thereto. The interlayer insulating films 160 and 180 may have a plurality of contact holes, wherein the contact holes are filled with a conductor to form a plurality of contacts 161, 162, and 150.

The bit line 120 may be formed between the interlayer insulating films 160 and 180. The bit line 120 may be electrically connected to the drain region 175 of the transistor 100 through the contact 162. The bit line 120 may be disposed to cross a word line (not shown), wherein the bit line 120 and the word line may form a plurality of arrays. The word line may be electrically connected to the gate electrode 124.

The capacitor 100 may be buried in the interlayer insulating film 180 and specifically, in a trench 181 formed in the interlayer insulating film 180. The shape of the trench 181 is not limited, for example, a connection part of a bottom surface and a side surface of the trench 181 may have a round shape or the opposite sides of the trench may have inclined shapes at a predetermined angle. The trench 181 may have a high aspect ratio, and the greater the aspect ratio, the capacitance of the capacitor 100 may be greater. The capacitor 100 may be electrically connected to the source region 173 of the transistor 200 through the contact 161.

The capacitor 100 is the same as aforementioned and includes the first electrode 10, the dielectric film 30, and the second electrode 20. The first electrode 10 includes the first conductive layer 11 and the second conductive layer 12, and the descriptions of the first conductive layer 11 and the second conductive layer 12 are the same as above.

For example, the first conductive layer 11 may include a metal oxide such as a molybdenum oxide of the formula MoOₓ wherein 2≤x≤3, and the second conductive layer 12 may include a topological material. For example, the first conductive layer 11 and the second conductive layer 12 may include at least one same metal element, wherein for example, the first conductive layer 11 may include a molybdenum oxide of the formula MoOₓ wherein 2≤x≤3, and the topological material of the second conductive layer 12 may include MoP, MON, MOC, MoTe₂, MoSTe, MoSi₂, MoSeTe, Mo_{(1-z)}W_{z}Te₂ wherein 0<z$1, or a combination thereof. Specific description thereof is the same as described above.

The first conductive layer 11 and the second conductive layer 12 may be disposed along an interior wall of the interlayer insulating film 180 in the trench 181. The first conductive layer 11 and the second conductive layer 12 may be thin films, for example, continuous thin films with a substantially uniform thickness formed along the interior wall of the interlayer insulating film 180 in the trench 181. For example, the first conductive layer 11 and the second conductive layer 12 may be respectively formed through atomic layer deposition (ALD).

A total thickness of the first conductive layer 11 and the second conductive layer 12 may be about 1 nm to about 50 nm, about 1 nm to about 40 nm, about 1 nm to about 30 nm, about 1 nm to about 20 nm, about 1 nm to about 15 nm, about 1 nm to about 10 nm, about 1 nm to about 9 nm, about 1 nm to about 7 nm, about 1 nm to about 5 nm, or about 1 nm to about 4 nm.

A thickness ratio of the first conductive layer 11 and the second conductive layer 12 may be about 1:9 to about 9:1, about 2:8 to about 8:2, about 3:7 to about 7:3, about 4:6 to about 6:4, or about 5:5. For example, the first conductive layer 11 may be thicker than the second conductive layer 12, and for example, the first conductive layer 11 may be about 1.5 times to about 20 times, about 2 times to about 20 times, or about 5 times to about 20 times thicker than the second conductive layer 12.

The dielectric film 30 may be disposed on the first electrode 10 along the interior wall of the interlayer insulating film 180 in the trench 181. The dielectric film 30 also may be a thin film, for example, a continuous thin film with a uniform thickness formed along the interior wall of the interlayer insulating film 180 in the trench 181.

The dielectric film 30 may include a high-k dielectric material capable of being epitaxially grown on the second conductive layer 12. For example, the dielectric film 30 may include a dielectric material which is a product of epitaxial growth on the first surface of the second conductive layer 12. The second conductive layer 12 may include a molybdenum-containing topological material, the dielectric film 30 may include TePb, PbSe, PbS, Bi₂Te₃, TiO₂, Bi₂Se₃, LiNbO₃, LiTaO₃, Ge(Bi₃O₅)₄, LaAlO₃, CeO₂, Ge, InSb, GaSb, NdGaO₃, ZrO₂, TeO₂, InP, GaAs, YAlO₃, Te₂Mo, CdWO₄, or a combination thereof.

A thickness of the dielectric film 30 may be about 1 nm to about 100 nm, about 2 nm to about 80 nm, about 2 nm to about 50 nm, or about 2 nm to about 30 nm.

The second electrode 20 may fill the interior of the trench 181. However, the present disclosure is not limited thereto, and the second electrode 20 may fill a portion of the trench 181 and a filler material may be disposed on the second electrode 20 in the trench 181. The second electrode 20 may include, for example, a metal, a metal nitride, a metal oxide, a metal oxynitride, or a combination thereof, for example Ti, TIN, TION, TaN, MON, CON, TiAlN, TaAlN, W, WO_{y} wherein 2≤y≤3, Ru, RuO₂, SrRiO₃, Ir, IrO₂, Pt, PtO, SrRuO₃, or a combination thereof, but is not limited thereto.

The contact 150 may be disposed in the interlayer insulating film 180, and the bit line 120 is electrically connected to an upper wire through the contact 150. A barrier layer 170 may be formed around the contact 150.

One or two or more interlayer insulating films 190 and 195 may be disposed on the capacitor 100, and the capacitor 100 may be electrically connected to a wire (not shown) buried in the interlayer insulating films 190 and 195.

In FIG. 4, as the capacitor 100 in FIG. 4, a structure of the capacitor 100 of FIG. 1 is shown, but not limited thereto, and may be that of the capacitor 100 shown in FIG. 2 or 3.

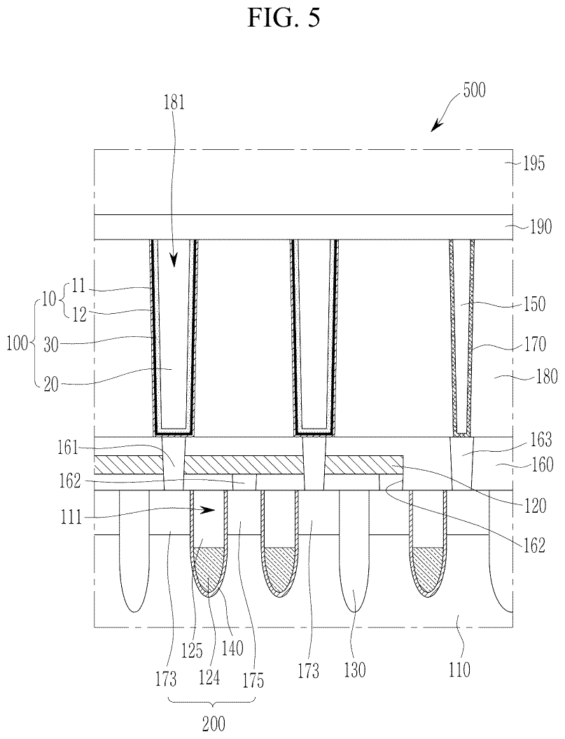

FIG. 5 is a cross-sectional view illustrating an embodiment of a semiconductor device.

Referring to FIG. 5, in an embodiment of the semiconductor device 500, like in the aforementioned embodiments, includes the semiconductor substrate 110, a transistor 200, and the capacitor 100.

However, the semiconductor device 500 according to the present embodiments may include the transistor 200 with a BCAT (buried cell array transistor) structure such that the gate electrode 124 and the gate insulating layer 140 may be buried in the semiconductor substrate 110.

Specifically, the transistor 200 may have a plurality of trenches 111. The trenches 111 may be formed to have a predetermined depth from the surface of the semiconductor substrate 110 and expose an interior wall of the semiconductor substrate 110. The shape of the trenches 111 is not limited, for example, a connection part of a bottom surface and a side surface of the trench 181 may have a round shape or the opposite sides of the trench may have inclined shapes at a predetermined angle.

The gate insulating layer 140 may be disposed along the interior wall of the semiconductor substrate 110 in the trench 111. The gate insulating layer 140 may be a thin film, for example, a continuous thin film with a substantially uniform thickness along the interior wall of the semiconductor substrate 110 in the trench 111. The thickness of the gate insulating layer 140 may be, for example, about 1 nm to about 30 nm, about 3 nm to about 20 nm, or about 5 nm to about 10 nm.

The gate insulating layer 140 may include a gate dielectric, and the gate dielectric may include, for example, an oxide, a nitride, an oxynitride, or a combination thereof including silicon, aluminum, hafnium, lanthanum, zirconium, tantalum, yttrium, titanium, barium, strontium, or an alloy thereof, but is not limited thereto.

The gate electrode 124 may fill a portion of the trench 111. However, the gate electrode 124 is not limited thereto but may be a continuous thin film disposed on the gate insulating layer 140 along the interior wall of the semiconductor substrate 110 in the trench 111. The gate electrode 124 may include a low resistance conductor, for example Ti, TIN, TION, or a combination thereof. The thickness of the gate electrode 124 may be for example about 1 nm to about 30 nm, about 3 nm to about 20 nm, or about 5 nm to about 10 nm.

A filling conductive layer 125 may be disposed on the gate electrode 124. The filling conductive layer 125 may be disposed in the trench 111 and electrically connected with a word line (not shown). The filling conductive layer 125 may include Ti, TIN, TION, tungsten, or a combination thereof but is not limited thereto.

In FIG. 5, the structure of the capacitor 100 of FIG. 1 is shown, but that of the capacitor 100 shown in FIG. 2 or 3 may be equally applicable without any particular limitation.

In the above, a DRAM device, which is a type of the semiconductor device, is described, but the present disclosure is not limited thereto, but may be applied to all semiconductor devices including capacitors. For example, the capacitors and the semiconductor devices may be used for arithmetic operations, program execution, temporary data retention, and/or the like.

The above capacitors and/or semiconductor devices may be included in various electronic devices. The electronic devices may be, for example, mobile devices, computers, laptops, tablet personal computers, smart watches, sensors, digital cameras, electronic books, network devices, car navigators, Internet of Things (IoT), Internet of Everything (loE), drones, door locks, safes, automated teller machines (ATMs), security devices, medical devices, automobile electrical components, or the like but are not limited thereto.

For example, the electronic devices may include a memory unit, an arithmetic logic unit, and a control unit, which may be electrically connected. For example, the memory unit, the arithmetic logic unit, and the control unit may be implemented as one chip, for example, monolithically integrated into one chip on one substrate. The memory unit, the arithmetic logic unit, and the control unit may independently include the above capacitors and/or semiconductor devices. The electronic devices may be connected to one or more input/output devices.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A capacitor, comprising:
a first electrode comprising a topological material,
a second electrode facing the first electrode, and
a dielectric film between the first electrode and the second electrode.

2. The capacitor of claim 1, wherein the first electrode comprises:
a first conductive layer comprising a conductor, and
a second conductive layer comprising the topological material,
wherein the conductor and the topological material are different in chemical composition.

3. The capacitor of claim 2, wherein the conductor included in the first conductive layer comprises a metal oxide.

4. The capacitor of claim 3, wherein the conductor included in the first conductive layer comprises molybdenum oxide.

5. The capacitor of claim 3, wherein the topological material and the metal oxide comprise at least one same metal element.

6. The capacitor of claim 5, wherein the topological material and the metal oxide each comprise molybdenum.

7. The capacitor of claim 6, wherein
the metal oxide comprises a molybdenum oxide of the formula MoOₓ wherein 2≤x≤3, and
the topological material comprises MoP, MON, MOC, MoTe₂, MoSTe, MoSi₂, MoSeTe, Mo_{(1-z)}W_{z}Te₂ wherein 0<z$1, or a combination thereof.

8. The capacitor of claim 2, wherein
a first surface of the second conductive layer is in contact with the dielectric film, and
an opposite second surface of the second conductive layer is in contact with the first conductive layer.

9. The capacitor of claim 8, wherein the dielectric film comprises a dielectric material which is a product of epitaxial growth on the first surface of the second conductive layer having a dielectric constant that is greater than a dielectric constant of silicon oxide.

10. The capacitor of claim 9, wherein
the topological material comprises MoP, MON, MoC, MoTe₂, MoSTe, MoSi₂, MoSeTe, Mo_{(1-z)}W_{z}Te₂ wherein 0<z≤1, or a combination thereof, and the dielectric comprises TePb, PbSe, PbS, Bi₂Te₃, TiO₂, Bi₂Se₃, LiNbO₃, LiTaO₃, Ge(BisO₅)₄, LaAlO₃, CeO₂, Ge, InSb, GaSb, NdGaO₃, ZrO₂, TeO₂, InP, GaAs, YAlO₃, Te₂Mo, CdWO₄, or a combination thereof.

11. The capacitor of claim 2, wherein the first electrode further comprises a third conductive layer spaced apart from the second conductive layer, the third conductive layer disposed on a surface of the first conductive layer.

12. The capacitor of claim 11, wherein the third conductive layer comprises the topological material, Ti, TIN, TION, or a combination thereof.

13. A semiconductor device comprising:
a semiconductor substrate,
a transistor, wherein the transistor is integrated into the semiconductor substrate or disposed on the semiconductor substrate, and
the capacitor of claim 1, the capacitor being electrically connected to the transistor.

14. A semiconductor device comprising:
a semiconductor substrate,
a transistor, wherein the transistor is integrated into the semiconductor substrate or disposed on the semiconductor substrate, and
a capacitor electrically connected to the transistor and comprising a first electrode, a dielectric film, and a second electrode,
wherein the first electrode comprises
a first conductive layer comprising a first conductor, and
a second conductive layer in contact with the dielectric film and comprising a second conductor of a different chemical composition than the first conductor, and
wherein the first conductor and the second conductor comprise at least one same metal element.

15. The semiconductor device of claim 14, wherein a resistivity of the first electrode is less than a resistivity of the first conductive layer.

16. The semiconductor device of claim 14, wherein
the first conductor comprises a molybdenum oxide of the formula MoOₓ wherein 2≤x≤3, and
the second conductor comprises MoP, MON, MOC, MoTe₂, MoSTe, MoSi₂, MoSeTe, Mo_{(1-z)}W_{z}Te₂ wherein 0<z≤1, or a combination thereof.

17. The semiconductor device of claim 13, wherein the first electrode further comprises a third conductive layer disposed on a surface of the first conductive layer and comprising the topological material, Ti, TIN, TION, or a combination thereof.

18. The semiconductor device of claim 14, further comprising an interlayer insulating film on the transistor,
wherein the capacitor is formed in a trench in the interlayer insulating film.

19. An electronic device comprising the capacitor of claim 1.

20. An electronic device comprising the semiconductor device of claim 13.

21. A method of manufacturing a capacitor, the method comprising:
depositing a conductor on a substrate to form a first conductive layer;
disposing a second conductive layer on the first conductive layer to form a first electrode;
disposing a dielectric film on the first electrode, wherein the second conductive layer is disposed between the dielectric film and the first conductive layer to form a composite; and
disposing a second electrode on the composite,
wherein the dielectric film is disposed between the first electrode and the second electrode to manufacture the capacitor,
wherein the second conductive layer comprises a topological material, the first conductive layer comprises a metal oxide, and the topological material and the metal oxide comprise at least one same metal element.
